(19) United States
(12) Patent Application Publication
(10) Pub. No.: US 2024/0357916 A1
(43) Pub. Date: Oct. 24, 2024

(54) OPTICAL PANEL CUTTING DEVICE AND METHOD, GLASS PANEL FOR DISPLAY DEVICE CUT BY OPTICAL PANEL CUTTING, AND METHOD OF MANUFACTURING DISPLAY DEVICE WITH OPTICAL PANEL CUTTING

(71) Applicant: Samsung Display Co., LTD., Yongin-si (KR)

(72) Inventors: SEUNG-HOON JANG, Yongin-si (KR); Konstantin MISHCHIK, Yongin-si (KR); Hyung Sik KIM, Yongin-si (KR); SUNGGYU PARK, Yongin-si (KR)

(73) Assignee: Samsung Display Co., LTD., Yongin-si (KR)

(21) Appl. No.: 18/420,539

(22) Filed: Jan. 23, 2024

(30) Foreign Application Priority Data
Apr. 21, 2023 (KR) 10-2023-0052839

(51) Int. Cl. H10K 71/00; B23K 26/38; G02B 26/02; G02B 27/09; G02B 27/10

(52) U.S. Cl. CPC H10K 71/851; B23K 26/38; G02B 26/02; G02B 27/0927; G02B 27/1093

(57) ABSTRACT

An embodiment of the disclosure provides an optical panel cutting device, including: a light converter that converts an incident beam into a Bessel beam; a projection lens that amplifies energy of a beam outgoing from the light converter; a beam splitter that splits a beam outgoing from the projection lens; and an objective lens that amplifies a beam outgoing from the beam splitter to cut a panel, wherein the beam outgoing from the objective lens includes a first peak and at least one second peak, and the at least one second peak has a lower intensity than the first peak.

### CROSS-REFERENCE TO RELATED APPLICATION

This application claims priority to and the benefit of Korean Patent Application No. 10-2023-0052839 under 35 U.S.C. § 119 filed in the Korean Intellectual Property Office (KIPO) on Apr. 21, 2023, the entire contents of which are incorporated herein by reference.

### BACKGROUND

### 1. Technical Field

The disclosure relates to a panel cutting device and method, and more particularly, to an optical panel cutting device and method, a glass panel for a display device cut by optical panel cutting, and a method of manufacturing a display device using optical panel cutting.

### 2. Description of the Related Art

A display device is generally formed on a substrate such as glass, and a manufacturing method thereof includes forming several cells on a large substrate and then cutting the substrate to separate the cells. Subsequently, chamfering of the cut surface of each cell, which is a complicated and costly process, is performed to smooth the cut surface.

### SUMMARY

The disclosure has been in an effort to provide a device and method that may readily perform panel cutting and cut surface rounding or chamfering.

The technical objectives to be achieved by the disclosure are not limited to those described herein, and other technical objectives that are not mentioned herein would be clearly understood by a person skilled in the art from the description of the disclosure.

An embodiment of the disclosure provides an optical panel cutting device, including a light converter that converts an incident beam into a Bessel beam; a projection lens that amplifies energy of a beam outgoing from the light converter; a beam splitter that splits a beam outgoing from the projection lens; and an objective lens that amplifies a beam outgoing from the beam splitter to cut a panel, wherein the beam outgoing from the objective lens includes a first peak and at least one second peak, and the at least one second peak has a lower intensity than the first peak.

The beam splitter may include a diffractive optical element having a plurality of patterns.

The diffractive optical element may be rotatable around an axis perpendicular to a propagating direction of the beam outgoing from the projection lens.

A relative intensity of the at least one second peak may be in a range of about 30% to about 90% of an intensity of the first peak, and the relative intensity of the at least one second peak may be adjusted by rotating the diffractive optical element to change an angle formed between an incident surface of the diffractive optical element and an outgoing surface of the projection lens.

A distance between the first peak and the at least one second peak may be in a range of about 3 μm to about 30 μm, and a diameter of each of the first peak and the at least one second peak may be in a range of about 2 μm to about 5 μm.

The at least one second peak may include two second peaks symmetrically arranged with respect to the first peak.

The beam outgoing from the objective lens has a plurality of combinations of the first peak and the at least one second peak arranged in a row.

Another embodiment of the disclosure provides an optical panel cutting method, including generating an outgoing beam of an optical panel cutting device having a first peak and at least one second peak; aligning the outgoing beam and a panel; and cutting the panel by irradiating the outgoing beam to the panel, wherein the at least one second peak has a lower intensity than the first peak.

A relative intensity of the at least one second peak may be in a range of about 30% to 90% of an intensity of the first peak.

A distance between the first peak and the at least one second peak may be in a range of about 3 μm to about 30 μm, and a diameter of each of the first peak and the at least one second peak may be in a range of about 2 μm to about 5 μm.

A thickness of the panel may be in a range of about 30 μm to about 500 μm.

The at least one second peak comprise two second peaks symmetrically arranged with respect to the first peak.

The outgoing beam has a plurality of combinations of the first peak and the at least one second peak arranged in a row.

Another embodiment of the disclosure provides a glass panel for a display device including a plurality of pixels, wherein: a cross-section of an edge of the glass panel has a shape of an arc, and a thickness of the glass panel may be in a range of about 30 μm to about 500 μm.

A radius of the arc may be in a range of about 1.5 mm to about 6 mm.

The edge of the glass panel may be formed by irradiating a beam having two peaks and performing isotropic etching.

Another embodiment of the disclosure provides a method of manufacturing a display device, including forming a plurality of display device cells on a panel; generating an outgoing beam of an optical panel cutting device having a first peak and a second peak; aligning the outgoing beam and the panel; and separating the plurality of display device cells by exposing the panel to the outgoing beam to cut the panel, wherein the second peak has a lower intensity than the first peak.

A relative intensity of the second peak may be in a range of about 30% to about 90% of an intensity of the first peak, a distance between the first peak and the second peak may be in a range of about 3 μm to about 30 μm, a diameter of each of the first peak and the second peak may be in a range of about 2 μm to about 5 μm, and a thickness of the panel may be in a range of about 30 μm to about 500 μm.

The method may further include after the separating of the plurality of display device cells, isotropically etching the plurality of display device cells to treat surfaces of the plurality of display device cells and to adjust a thickness of each of the plurality of display device cells.
after the etching of the plurality of display device cells, an edge cross-section of the panel has a shape of an arc with a radius in a range of about 1.5 mm to about 6 mm.

Accordingly, it is possible to cut a substrate and simultaneously process the cut surface to round or chamfer it.

### BRIEF DESCRIPTION OF THE DRAWINGS

FIG. 1 illustrates a schematic diagram of an example of an optical substrate cutting device according to an embodiment of the disclosure.

FIG. 2 schematically illustrates an outgoing beam of the substrate cutting device shown in FIG. 1.

FIG. 3 illustrates a schematic perspective view for explaining an operation of the substrate cutting device shown in FIG. 1.

FIG. 4 illustrates a schematic cross-sectional view of an example of a beam splitter of an optical substrate cutting device according to an embodiment of the disclosure.

FIG. 5 schematically illustrates an outgoing beam of the substrate cutting device shown in FIG. 1.

FIG. 6 illustrates a graph of an intensity according to a position of an outgoing beam of the substrate cutting device shown in FIG. 1.

FIGS. 7A-7E illustrate schematic cross-sectional views of results obtained by simulating a process of cutting a substrate by using an optical substrate cutting device according to an embodiment of the disclosure.

FIG. 8 illustrates a photograph of a cut surface of a substrate according to an experimental result of the disclosure, (a) illustrates a cut surface after laser irradiation, and (b) illustrates a cut surface after etching.

FIG. 9 illustrates a schematic diagram of a substrate cutting method according to another embodiment of the disclosure.

### DETAILED DESCRIPTION OF THE EMBODIMENTS

The disclosure will be described more fully hereinafter with reference to the accompanying drawings, in which embodiments of the disclosure are shown. As those skilled in the art would realize, the described embodiments may be modified in various different ways, all without departing from the spirit or scope of the disclosure.

In order to clearly describe the disclosure, parts or portions that are repetitive or irrelevant to the description may be omitted, and identical or similar constituent elements throughout the specification may be denoted by the same reference numerals.

Since the size and thickness of each part or portion shown in the drawing may be arbitrarily set for convenience of description, the disclosure is not limited thereto. In particular, in the drawing, the thickness may be enlarged and exaggerated in order to clearly express various layers and regions or areas and facilitate explanation.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

Unless explicitly described to the contrary, the word “comprise,” “include,” “have” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

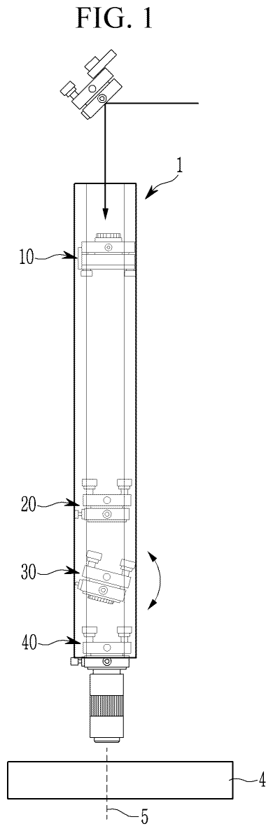

Hereinafter, an optical panel cutting device according to an embodiment of the disclosure will be described in detail with reference to FIG. 1 to FIG. 8.

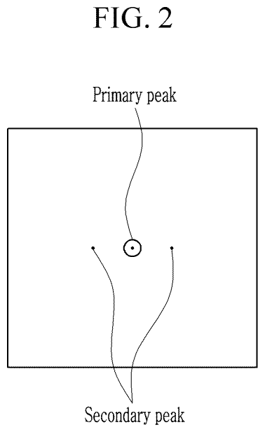

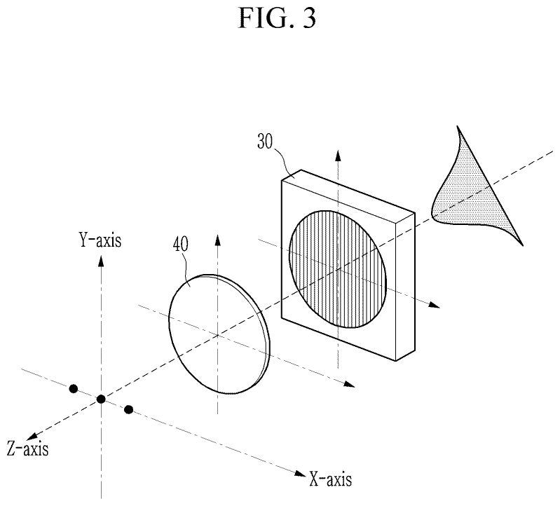

FIG. 1 illustrates a schematic diagram of an example of an optical panel cutting device according to an embodiment of the disclosure, FIG. 2 schematically illustrates an outgoing beam of the panel cutting device shown in FIG. 1, and FIG. 3 illustrates a schematic perspective view for an operation of the panel cutting device shown in FIG. 1.

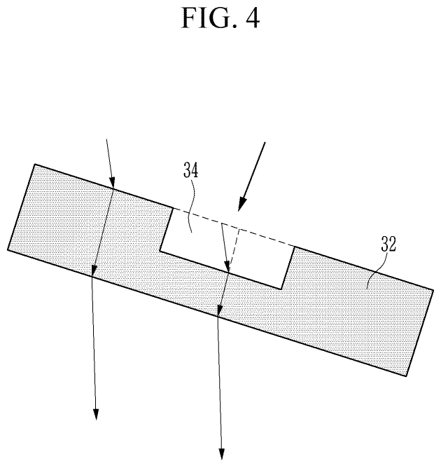

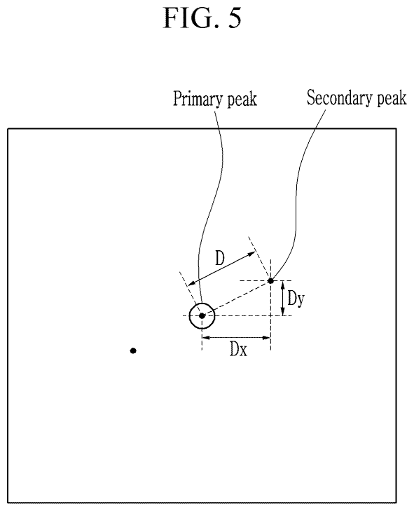

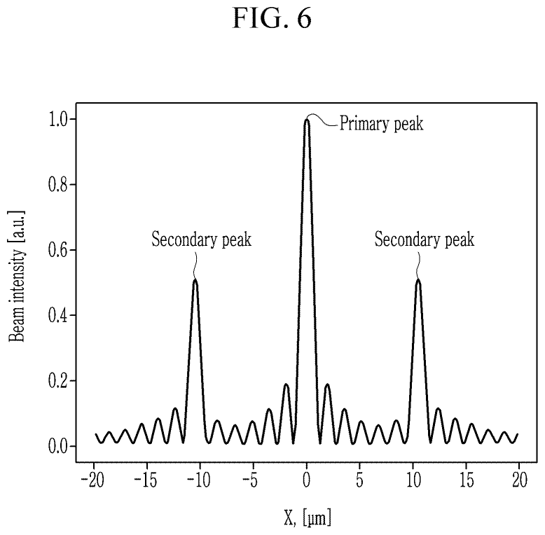

FIG. 4 is a schematic sectional view of a beam splitter of an optical panel cutting device according to an embodiment of the disclosure, FIG. 5 schematically illustrates an outgoing beam of the panel cutting device shown in FIG. 1, and FIG. 6 is a graph illustrating intensity as function of position of an outgoing beam of the panel cutting device shown in FIG. 1.

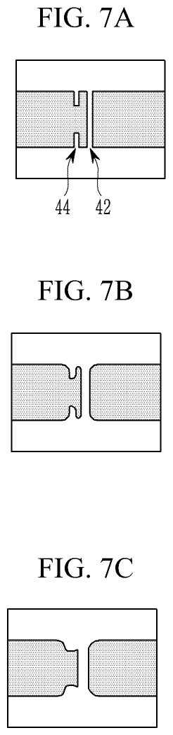

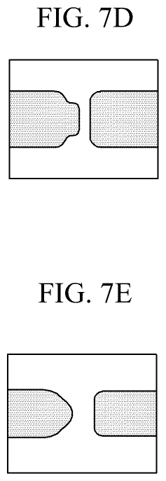

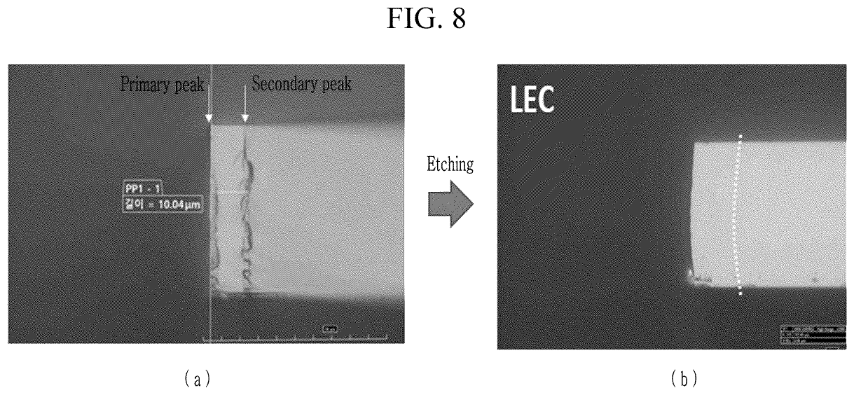

FIGS. 7A-7E are schematic sectional views of a panel during simulated (or virtual) panel cutting by using an optical panel cutting device according to an embodiment of the disclosure. FIG. 8 illustrates photographs showing a cut surface of a panel, after laser cut (a) by an optical panel cutting device and after etching (b) according to an experiment of the disclosure.

Referring to FIG. 1, an optical panel cutting device 1 according to an embodiment of the disclosure may include a light converter 10, a projection lens 20, a beam splitter 30, and an objective lens 40 that may be sequentially arranged. An incident beam such as a laser beam may be passed through these components 10, 20, 30, and 40 of the device 1 to be converted into an outgoing beam 5, which is used to cut a panel 4. One or more display device cells, for example, one or more organic light emitting device cells that may be included in the panel 4, may be separated by using the outgoing beam 5. The panel 4 may include an ultra-thin glass substrate with a thickness in a range of about 30 μm to about 500 μm. Each display device cell, which is to be a single display device after being separated, may include one or more pixels for displaying images, driving circuit(s) for driving the one or more pixels, and one or more pads for receiving external signals. The pixels, the driving circuits, and the pads may be formed through semiconductor processes such as depositing and etching of thin films such as conductive layers and insulating layers.

The light converter 10 may convert the shape of incident light, for example, laser beam inputted from the outside. The laser beam may include, for example, infrared (IR) laser beam. An example of the light converter 10 may be an axicon lens, which may have, for example, a planar incident surface and a conical outgoing surface and may convert incident light into a ring shape. The axicon lens may convert incident light having a Gaussian distribution into a non-diffractive Bessel beam. Since the Bessel beam described by a Bessel function of the first kind is non-diffractive, it may propagate without spreading out.

The projection lens 20 may be disposed at an output side of the light converter 10, and may increase the energy density of the beam outputted from the light converter 10. The projection lens 20 may include one or more convex lenses.

The beam splitter 30 may be disposed at the output side of the projection lens 20, and may split a peak of the beam passing through the projection lens 20 into two or more. The beam splitter 30 may include, for example, a diffractive optical element (DOE).

The objective lens 40 may be disposed at the output side of the beam splitter 30, and may increase the energy density of the beam outputted from the beam splitter 30. To this end, the objective lens 40 may include one or more convex lenses.

The outgoing beam of the optical panel cutting device 1 according to the embodiment of the disclosure may have, for example, as shown in FIG. 2 and FIG. 3, a primary peak disposed at a center and a pair of secondary peaks symmetrically arranged with respect to the primary peak, and the secondary peaks may have a weaker intensity than the primary peak. By using the above-described two peaks, cutting of the panel 4 and chamfering for smoothing edges of the cut surface of the panel 4 may be performed simultaneously. For example, during cutting the panel 4, the primary peak may be aligned with a portion to be removed from the panel 4 or an end of each cell (for example, 42 in FIG. 7A), while the secondary peak may be disposed inward (e.g., slightly inward) from the end (for example, 44 in FIG. 7A). Since the intensity of the secondary peak may be lower than the primary peak, the secondary peak may remove only a part of the panel 4 to a partial depth from the surface while the primary peak portion entirely cuts the panel 4. Therefore, by properly adjusting the time (or time period) exposing the panel 4 to the outgoing beam, a chamfer of a desired shape may be obtained while cutting the panel 4.

According to the embodiment of the disclosure, one or more combinations of a primary peak and secondary peaks may be arranged in a row, and the number of the combinations may be less than about 10.

The outgoing beam of the optical panel cutting device 1 according to an embodiment of the disclosure may have weak subsidiary peaks in addition to the primary and secondary peaks, but the intensity of the subsidiary peaks may be so small to be negligible.

A size of each peak may vary depending on a material and thickness of the panel 4, and, according to an embodiment of the disclosure, the diameter of each peak may be in a range of about 2 μm to about 5 μm.

The distance between the primary peak and the secondary peak and the relative intensity of the secondary peak with respect to the primary peak may be varied depending on the desired condition, such as a chamfering angle and depth, and according to the embodiment of the disclosure, the distance between the primary peak and the secondary peak may be in a range of about 3 μm to about 30 μm, and the relative intensity of the secondary peak with respect to the primary peak may be in a range of about 30% to about 90%. FIG. 6 is a graph of an intensity of an outgoing beam as a function of position according to an experimental example of the disclosure.

As described above, the beam splitter 30 according to an embodiment of the disclosure may include a diffractive optical element, and referring to FIG. 4, the diffractive optical element may include, for example, a plate-shaped body 32 having several cavity patterns 34. The body 32 may be rotatable around an axis perpendicular to a propagating direction of the beam, for example, an X-axis or a Y-axis in FIG. 3. Accordingly, by rotating the diffractive optical element, the incident surface of the diffractive optical element may make an angle (e.g., a predetermined or selectable angle) with the outgoing surface of the projection lens 20 disposed at the previous stage.

The variation of the angle made by the diffractive optical element with the outgoing surface may change the length through which the beam passes, resulting in the same effect as the depth of the pattern 34 being changed. For example, in case that the angle formed by the diffractive optical element with the outgoing surface increases, the distance (indicated by the arrow disposed within the pattern 34 in FIG. 4) that the beam travels within the pattern may increase, as in the case that the depth of the pattern 34 increases. Since the variation of the depth of the pattern 34 in turn may cause the intensity of the secondary peak to be changed, the intensity of the secondary peak may be adjusted by changing the angle formed by the diffractive optical element with the outgoing surface. For example, an intensity ratio of the secondary peak to the primary peak may be reduced by increasing the angle formed by the diffractive optical element with the outgoing surface.

Referring to FIG. 5, the positions of the secondary peaks may be symmetrically arranged with respect to the primary peak, and if desired, they may be arranged obliquely rather than horizontally. In this case, the distance (D) between the primary peak and the secondary peak may be obtained by measuring the displacement Dx in the x direction and the displacement Dy in the y direction.

A manufacturing method of a display device including a process of cutting a panel, for example, a panel for the display device by using the above-described device, will be described in detail below.

First, one or more display device cells are formed on a panel 4. The panel 4 may include an ultra-thin glass substrate with a thickness of about 500 μm or less. Each display device cell, which is to be a display device after being separated, may include one or more pixels for displaying images, driving circuits for driving the pixels, and one or more pads for receiving signals from the outside. The pixels, the driving circuits, and the pads may be formed by semiconductor processes such as depositing and etching of thin films such as conductive films and insulating films.

Subsequently, the panel 4 may be cut by using the optical panel cutting device 1 according to an embodiment to be divided into the cells. A cut surface of each cell may be chamfered.

Specifically, an incident beam such as a laser beam may be first incident on the optical panel cutting device 1 and converted into an outgoing beam by the optical panel cutting device 1. The laser beam may be, for example, an infrared laser beam having a Gaussian distribution, and the outgoing beam may be a Bessel beam having multiple peaks. According to an embodiment of the disclosure, the outgoing beam may include a primary peak and a pair of secondary peaks at both sides of the primary peak, the distance between the primary peak and the secondary peak may be in a range of about 3 μm to about 30 μm, and the relative intensity of the secondary peak with respect to the primary peak is in a range of about 30% to 90%. According to an embodiment of the disclosure, less than about 10 combinations of the primary and secondary peaks may be arranged in a row, and each peak may have a diameter in a range of about 2 μm to about 5 μm.

The distance between the primary peak and the secondary peak and the relative intensity of the secondary peak with respect to the primary peak may be varied by adjusting the beam splitter 30 of the cutting device 1 based on the material, thickness, and target shape of the cut surface of the panel 4. As described above, the diffractive optical element having a plate-shaped body with patterns may be used as the beam splitter 30, and an angle made by the diffractive optical element with the propagating direction of the beam may be adjusted to change the distance between the primary peak and the secondary peak and the relative intensity of the secondary peak with respect to the primary peak.

During the panel cutting, the cutting device 1 and the panel 4 may be arranged so that the primary peak may be aligned with a portion to be removed out of the panel 4 or an end of each cell (for example, 42 in FIG. 7A), while the secondary peak is disposed slightly inward from the end (for example, 44 in FIG. 7A).

Next, the outgoing beam of the cutting device 1 may be applied to the panel 4 for a time (e.g., a predetermined or selectable time or time period) to cut the panel 4. In an embodiment of the disclosure, since the intensity of the secondary peak may be lower than the primary peak, the secondary peak may remove only a part of the panel 4 to a partial depth from the surface while the primary peak portion entirely cuts the panel 4. Therefore, a chamfered cut surface may be obtained by properly adjusting the exposure time.

Finally, each cell divided from the panel 4 may be immersed in an etchant such as KOH to smooth the cut surface of the cell and simultaneously adjust the thickness of the cell. An example of the etching may include isotropic deep etching, and in this case, the thickness of the cells may be adjusted by changing the composition, temperature, and the like of the etchant and the exposure time to the etchant.

FIGS. 7A-7E show changes of the cut surface of the panel over time, and the shape of the cut surface about 1 second (FIG. 7A), about 30 seconds (FIG. 7B), about 60 seconds (FIG. 7C), about 75 seconds (FIG. 7D), and about 120 seconds (FIG. 7E) after the beginning of laser irradiation is shown, according to a simulated (or virtual) experiment of the disclosure.

However, the results of actual experiment were slightly different from the simulation. As shown in (a) of FIG. 8, after laser irradiation, a portion of the panel 4 exposed to the primary peak was entirely cut in a straight line, and a portion exposed to the secondary peak was cracked nearly along a straight line instead of forming a chamfer shown in FIG. 7E. After the etching process, where the cell having a cross-section shown in (a) of FIG. 8 was dipped into KOH, the edge of the cross section became a shape of an arc as shown in (b) of FIG. 8. A radius of the arc was in a range of about 1.5 mm to about 6 mm.

The use of the above-described optical panel cutting device 1 in cutting the panel 4 may form a round or chamfered cut surface without an additional chamfering process.

According to another embodiment of the disclosure, the cut surface of the panel 4 may be chamfered by using a single-peak outgoing beam instead of a multi-peak outgoing beam.

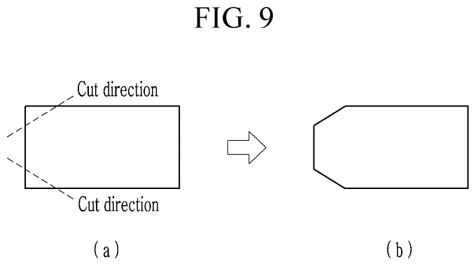

A panel cutting method according to another embodiment of the disclosure will be described in detail with reference to FIG. 9.

FIG. 9 schematically illustrates a panel cutting method according to another embodiment of the disclosure.

In an optical panel cutting device 1 according to another embodiment of the disclosure, the outgoing beam may have a single peak. In this case, the chamfer of the cut surface of the panel 4 may be obtained by exposing twice the panel 4 to the outgoing beam of the cutting device 1.

For example, after performing a first irradiation on the panel 4 with the outgoing beam to separate cells of the panel 4, chamfering may be performed by performing a second irradiation on each cell with the outgoing beam on a position slightly inward from the end of the cell. The second irradiation may be performed with the outgoing beam of a weaker intensity and/or for a shorter irradiation time compared with the first irradiation. The second irradiation may be applied to a position about 3 μm to about 5 μm away from the position of the first irradiation.

In another embodiment of the disclosure, the irradiation direction of the outgoing beam in the second irradiation may be oblique to the irradiation direction of the outgoing beam in the first irradiation. For example, referring to FIG. 9, the panel 4 may be cut by irradiating the outgoing beam in the second irradiation in a “cutting direction” oblique to the cut surface after the first irradiation. In this case, the intensity and irradiation time of the outgoing beam in the second irradiation may be the same as those in the first irradiation.

As described above, in the embodiments of the disclosure, a chamfered cut surface may be obtained by irradiating once a panel with an outgoing beam having multiple peaks of different intensities to cut it, or by irradiating two or more times a panel with an outgoing beam having a single peak to cut it.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. An optical panel cutting device, comprising:
a light converter that converts an incident beam into a Bessel beam;
a projection lens that amplifies energy of a beam outgoing from the light converter;
a beam splitter that splits a beam outgoing from the projection lens; and
an objective lens that amplifies a beam outgoing from the beam splitter to cut a panel, wherein
the beam outgoing from the objective lens includes a first peak and at least one second peak, and
the at least one second peak has a lower intensity than the first peak.

2. The optical panel cutting device of claim 1, wherein the beam splitter comprises a diffractive optical element having a plurality of patterns.

3. The optical panel cutting device of claim 2, wherein the diffractive optical element is rotatable around an axis perpendicular to a propagating direction of the beam outgoing from the projection lens.

4. The optical panel cutting device of claim 3, wherein
a relative intensity of the at least one second peak is in a range of about 30% to about 90% of an intensity of the first peak, and
the relative intensity of the at least one second peak is adjusted by rotating the diffractive optical element to change an angle formed between an incident surface of the diffractive optical element and an outgoing surface of the projection lens.

5. The optical panel cutting device of claim 4, wherein
a distance between the first peak and the at least one second peak is in a range of about 3 to about 30 μm, and
a diameter of each of the first peak and the at least one second peak is in a range of about 2 μm to about 5 μm.

6. The optical panel cutting device of claim 3, wherein the at least one second peak comprises two second peaks symmetrically arranged with respect to the first peak.

7. The optical panel cutting device of claim 6, wherein the beam outgoing from the objective lens has a plurality of combinations of the first peak and the at least one second peak arranged in a row.

8. An optical panel cutting method, comprising:
generating an outgoing beam of an optical panel cutting device having a first peak and at least one second peak;
aligning the outgoing beam and a panel; and
cutting the panel by irradiating the outgoing beam to the panel,
wherein the at least one second peak has a lower intensity than the first peak.

9. The optical panel cutting method of claim 8, wherein a relative intensity of the at least one second peak is in a range of about 30% to about 90% of an intensity of the first peak.

10. The optical panel cutting method of claim 9, wherein
a distance between the first peak and the at least one second peak is in a range of about 3 μm to about 30 μm, and
a diameter of each of the first peak and the at least one second peak is in a range of about 2 μm to about 5 μm.

11. The optical panel cutting method of claim 10, wherein a thickness of the panel is in a range of about 30 μm to about 500 μm.

12. The optical panel cutting method of claim 8, wherein the at least one second peak comprise two second peaks symmetrically arranged with respect to the first peak.

13. The optical panel cutting method of claim 12, wherein the outgoing beam has a plurality of combinations of the first peak and the at least one second peak arranged in a row.

14. A glass panel for a display device including a plurality of pixels, wherein
a cross-section of an edge of the glass panel has a shape of an arc, and
a thickness of the glass panel is in a range of about 30 μm to about 500 μm.

15. The glass panel for the display device of claim 14, wherein a radius of the arc is in a range of about 1.5 mm to about 6 mm.

16. The glass panel for the display device of claim 15, wherein the edge of the glass panel is formed by irradiating a beam having two peaks and performing isotropic etching.

17. A method of manufacturing a display device, comprising:
forming a plurality of display device cells on a panel;
generating an outgoing beam of an optical panel cutting device having a first peak and a second peak;
aligning the outgoing beam and the panel; and
separating the plurality of display device cells by exposing the panel to the outgoing beam to cut the panel,
wherein the second peak has a lower intensity than the first peak.

18. The method of claim 17, wherein
a relative intensity of the second peak is in a range of about 30% to about 90% of an intensity of the first peak,
a distance between the first peak and the second peak is in a range of about 3 μm to about 30 μm,
a diameter of each of the first peak and the second peak is in a range of about 2 μm to about 5 μm, and
a thickness of the panel is in a range of about 30 μm to about 500 μm.

19. The method of claim 18, further comprising:
after the separating of the plurality of display device cells, isotropically etching the plurality of display device cells to treat surfaces of the plurality of display device cells and to adjust a thickness of each of the plurality of display device cells.

20. The method of claim 19, wherein after the etching of the plurality of display device cells, an edge cross-section of the panel has a shape of an arc with a radius in a range of about 1.5 mm to about 6 mm.
